(19) United States
(12) Patent Application Publication
(10) Pub. No.: US 2025/0081545 A1
(43) Pub. Date: Mar. 6, 2025

(54) SEMICONDUCTOR DEVICE AND METHOD FOR MANUFACTURING SEMICONDUCTOR DEVICE

(71) Applicant: Mitsubishi Electric Corporation, Tokyo (JP)

(72) Inventors: Masaki SUDO, Chiyoda-ku, Tokyo (JP); Hiroto ADACHI, Chiyoda-ku, Tokyo (JP)

(73) Assignee: Mitsubishi Electric Corporation, Tokyo (JP)

(21) Appl. No.: 18/727,248

(22) PCT Filed: Jan. 31, 2022
(86) PCT No.: PCT/JP2022/003605

§ 371 Date: Jul. 8, 2024

(51) Int. Cl. H01L 29/06; H01L 21/265; H01L 21/266; H01L 29/40; H01L 29/66; H01L 29/739

(52) U.S. Cl. CPC H10D 62/107; H01L 21/26513; H01L 21/266; H10D 12/038; H10D 12/481; H10D 64/117

(57) ABSTRACT

A semiconductor device includes a semiconductor substrate, a plurality of element trenches, and a plurality of termination trenches. The semiconductor substrate includes an element region and a termination region. The element trench has a depth larger than the thickness of a second diffusion layer. The termination trench has a depth larger than the thickness of a first diffusion layer. An interval between the plurality of element trenches is a first trench interval L1. An interval between the element trench included in the plurality of element trenches and situated closest to the termination region and the termination trench included in the plurality of termination trenches and situated closest to the element region is a second trench interval L2. In this case, the first trench interval L1 and the second trench interval L2 are in a relation of L1≤L2≤1.5×L1.

### TECHNICAL FIELD

The present disclosure relates to a semiconductor device and a method for manufacturing the semiconductor device.

### BACKGROUND ART

A semiconductor device where a plurality of trenches are provided in a termination region surrounding an element region has been used to date. Such a semiconductor device where a plurality of trenches are provided in a termination region is described in, for example, Japanese Patent Laying-Open No. 2019-117867 (PTL 1). In the semiconductor device described in PTL 1, a withstand voltage can be maintained without forming a diffusion layer having a depth approximately equal to that of a trench gate.

### CITATION LIST

### Patent Literature

PTL 1: Japanese Patent Laying-Open No. 2019-117867

### SUMMARY OF INVENTION

### Technical Problem

In the semiconductor device described in PTL 1, trench intervals vary largely on a boundary between an element region and a termination region. Additionally, electric field concentration is caused near a portion where the trench interval is wide. Thus, further increase in withstand voltage of an element is limited.

The present disclosure has been made in view of the foregoing problem and is aimed at providing a semiconductor device high in withstand voltage and a method for manufacturing the semiconductor device by relaxing electric field concentration.

### Solution to Problem

A semiconductor device of the present disclosure includes a semiconductor substrate, a plurality of element trenches, and a plurality of termination trenches. The semiconductor substrate includes a first surface and a second surface opposite to each other and includes an element region and a termination region provided so as to surround the element region. The plurality of element trenches are provided in the element region and structured so as to extend from the first surface toward the second surface. The plurality of termination trenches are provided in the termination region and structured so as to extend from the first surface toward the second surface. The semiconductor substrate includes a drift layer of a first conductivity type, a first diffusion layer, and a second diffusion layer. The first diffusion layer is situated in the first surface in the termination region and is of a second conductivity type different from the first conductivity type of the drift layer. The second diffusion layer is situated in the first surface in the element region and is of the second conductivity type. The element trench has a depth larger than a thickness of the second diffusion layer. The termination trench has a depth larger than a thickness of the first diffusion layer. An interval between the element trench included in the plurality of element trenches and situated closest to the termination region and the element trench adjacent to the element trench situated closest to the termination region is a first trench interval L1. An interval between the element trench included in the plurality of element trenches and situated closest to the termination region and the termination trench included in the plurality of termination trenches and situated closest to the element region is a second trench interval L2. In this case, the first trench interval L1 and the second trench interval L2 are in a relation of L1≤L2≤1.5×L1.

### Advantageous Effects of Invention

In the semiconductor device according to the present disclosure, first trench

interval L1 and second trench interval L2 are in a relation of L1≤L2≤1.5×L1. Thus, a semiconductor device high in withstand voltage can be attained by relaxing electric field concentration.

### BRIEF DESCRIPTION OF DRAWINGS

FIG. 1 is a plan view that schematically illustrates a semiconductor device according to Embodiment 1.

FIG. 2 is a cross-sectional view along line II-II in FIG. 1.

FIG. 3 is a cross-sectional view that schematically illustrates a semiconductor device according to Embodiment 2.

FIG. 4 is a cross-sectional view that schematically illustrates a semiconductor device according to Embodiment 3.

FIG. 5 is a cross-sectional view that schematically illustrates Variation 1 of the semiconductor device according to Embodiment 3.

FIG. 6 is a cross-sectional view that schematically illustrates Variation 2 of the semiconductor device according to Embodiment 3.

FIG. 7 is a cross-sectional view that schematically illustrates a semiconductor device according to Embodiment 4.

FIG. 8 is a cross-sectional view that schematically illustrates a semiconductor device according to Embodiment 5.

FIG. 9 is a cross-sectional view that schematically illustrates Step 1 in a method for manufacturing the semiconductor device according to Embodiment 5.

FIG. 10 is a cross-sectional view that schematically illustrates Step 2 in the method for manufacturing the semiconductor device according to Embodiment 5.

FIG. 11 is a cross-sectional view that schematically illustrates Step 3 in the method for manufacturing the semiconductor device according to Embodiment 5.

FIG. 12 is a cross-sectional view that schematically illustrates Step 4 in the method for manufacturing the semiconductor device according to Embodiment 5.

FIG. 13 is a cross-sectional view that schematically illustrates Step 5 in the method for manufacturing the semiconductor device according to Embodiment 5.

FIG. 14 is a cross-sectional view that schematically illustrates Step 6 in the method for manufacturing the semiconductor device according to Embodiment 5.

FIG. 15 is a cross-sectional view that schematically illustrates Step 7 in the method for manufacturing the semiconductor device according to Embodiment 5.

FIG. 16 is a cross-sectional view that schematically illustrates Step 1 in a variation of the method for manufacturing the semiconductor device according to Embodiment 5.

FIG. 17 is a cross-sectional view that schematically illustrates Step 2 in the variation of the method for manufacturing the semiconductor device according to Embodiment 5.

FIG. 18 is a cross-sectional view that schematically illustrates Step 3 in the variation of the method for manufacturing the semiconductor device according to Embodiment 5.

FIG. 19 is a cross-sectional view that schematically illustrates Step 4 in the variation of the method for manufacturing the semiconductor device according to Embodiment 5.

FIG. 20 is a cross-sectional view that schematically illustrates Step 5 in the variation of the method for manufacturing the semiconductor device according to Embodiment 5.

FIG. 21 is a cross-sectional view that schematically illustrates Step 6 in the variation of the method for manufacturing the semiconductor device according to Embodiment 5.

FIG. 22 is a cross-sectional view that schematically illustrates Step 7 in the variation of the method for manufacturing the semiconductor device according to Embodiment 5.

FIG. 23 is a cross-sectional view that schematically illustrates Step 8 in the variation of the method for manufacturing the semiconductor device according to Embodiment 5.

### DESCRIPTION OF EMBODIMENTS

Embodiments are described below on the basis of the drawings. Hereinafter, the same or corresponding portions are denoted by the same reference characters and overlapping descriptions thereof are not repeated.

### Embodiment 1

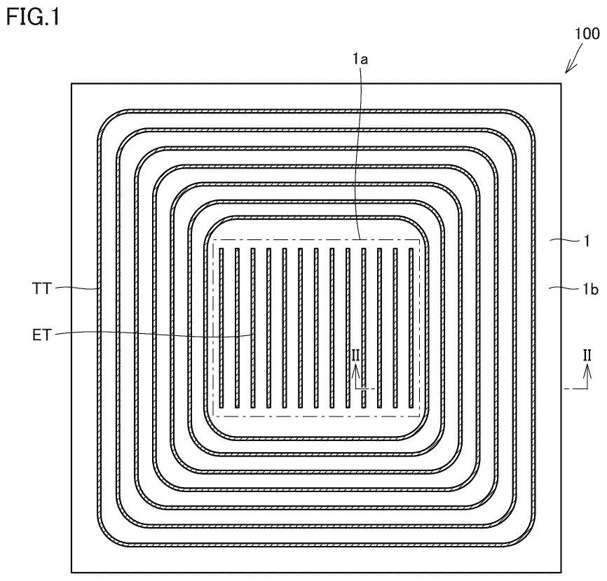

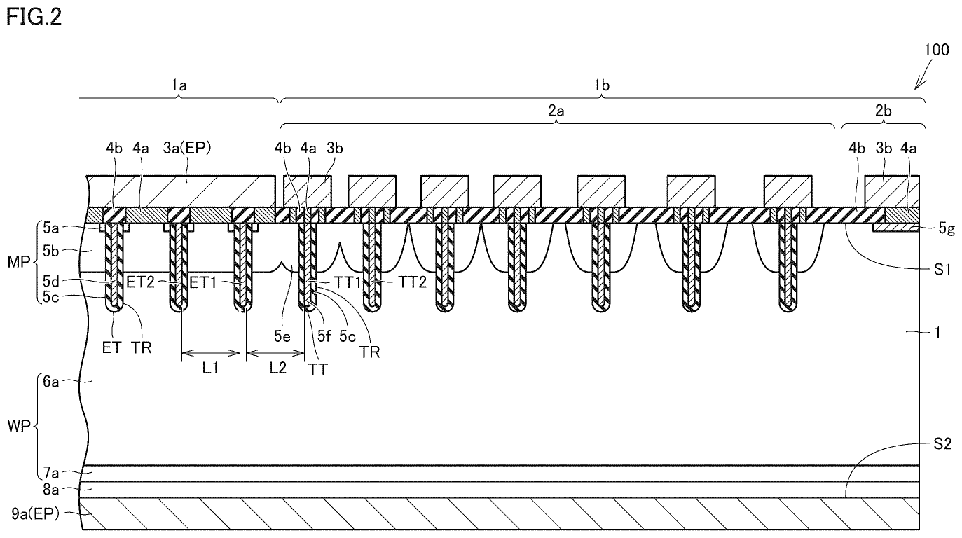

Referring to FIGS. 1 and 2, a configuration of a semiconductor device 100 according to Embodiment 1 is described. Semiconductor device 100 according to Embodiment 1 is an insulated gate bipolar transistor (IGBT). In an IGBT, a collector layer is formed on the back side of an element region. Semiconductor device 100 according to Embodiment 1 is not limited to an IGBT but may be a metal oxide semiconductor field effect transistor (MOSFET) or a reverse conductive (RC)-IGBT. In a MOSFET, a drain layer is formed on the back side of an element region. In an RC-IGBT, a cathode layer is formed in part of a collector layer on the back side of an element region. A semiconductor material is silicon (Si) for example. The semiconductor material is not limited to silicon (Si) but may be a silicon carbide (SiC).

Semiconductor device 100 according to Embodiment 1 includes a semiconductor substrate 1. Semiconductor substrate 1 includes a first surface S1 and a second surface S2 opposite to each other. Semiconductor substrate 1 includes an element region 1a and a termination region 1b. Element region 1a is structured so as to allow a main current to flow therethrough. In a plan view, element region 1a is situated in the center of semiconductor substrate 1. That is, when semiconductor substrate 1 is viewed from the first surface S1 side, element region 1a is situated in the center of semiconductor substrate 1. Termination region 1b is structured so as to maintain a withstand voltage in a horizontal direction of semiconductor device 100 in a state where a current is interrupted. Termination region 1b is provided so as to surround element region 1a. In a plan view, termination region 1b is situated so as to surround element region 1a.

Semiconductor substrate 1 includes an n drift layer 6a as a drift layer of a first conductivity type, a p diffusion layer 5e as a first diffusion layer, and a p base layer 5b as a second diffusion layer. P diffusion layer 5e as the first diffusion layer is situated in first surface S1 in termination region 1b. P diffusion layer 5e as the first diffusion layer is of a second conductivity type, which is different from the first conductivity type of n drift layer 6a as the drift layer. P base layer 5b as the second diffusion layer is situated in first surface S1 in element region 1a. P base layer 5b as the second diffusion layer is of the second conductivity type. Further, semiconductor substrate 1 includes an n source layer 5a, an n buffer layer 7a, a p collector layer 8a, and an n channel stop layer 5g.

In element region 1a, a MOS channel portion MP, a withstand voltage maintaining portion WP, p collector layer 8a, an electrode portion EP, an interlayer film 4b, and a plug 4a are provided. MOS channel portion MP is structured so as to control the flow of electrons. MOS channel portion MP includes n source layer 5a, p base layer 5b, an oxide film 5c, and a trench gate electrode 5d. Withstand voltage maintaining portion WP is structured so that a depletion layer expands in a state where a current is interrupted. Withstand voltage maintaining portion WP includes n drift layer 6a and n buffer layer 7a. P collector layer 8a is structured so that holes are injected in a state where a current is conducted. Electrode portion EP is structured so as to be connected to an external circuit. Electrode portion EP includes a collector electrode 9a and an emitter electrode 3a. Interlayer film 4b is structured so as to insulate upper and lower portions in different layers. Plug 4a is structured so as to allow interconnection between upper and lower portions in different layers.

N source layer 5a is provided in first surface S1. N source layer 5a is an n-type impurity region. Plug 4a and interlayer film 4b are provided on first surface S1. Emitter electrode 3a is provided on plug 4a and interlayer film 4b. N source layer 5a is conductively connected to emitter electrode 3a with plug 4a interposed therebetween. N source layer 5a is in contact with p base layer 5b. N source layer 5a is made away from n drift layer 6a with p base layer 5b interposed therebetween. P base layer 5b is a p-type impurity region. P base layer 5b is provided in first surface S1. P base layer 5b is the second diffusion layer. P base layer 5b is in contact with n drift layer 6a. N drift layer 6a is an n-type impurity region. N buffer layer 7a is provided on n drift layer 6a. N buffer layer 7a is an n-type impurity region. P collector layer 8a is provided on n buffer layer 7a. P collector layer 8a is a p-type impurity region. Collector electrode 9a is provided on p collector layer 8a.

A plurality of element trenches ET are provided in element region 1a. Element trench ET is structured so as to extend from first surface S1 toward second surface S2. Element trench ET has a depth larger than the thickness of p base layer 5b (the second diffusion layer). Element trench ET passes through p base layer 5b and is formed so as to be deeper than p base layer 5b. Element trench ET passes through n source layer 5a and p base layer 5b and reaches n drift layer 6a. Element trench ET includes oxide film 5c and trench gate electrode 5d. A trench TR is provided in element region 1a. Oxide film 5c is provided on the inner surface of trench TR. Trench gate electrode 5d is provided on oxide film 5c.

In termination region 1b, a field relaxation region 2a and a channel stop region 2b are provided. Field relaxation region 2a is structured so as to relax an electric field. Channel stop region 2b is structured so that no electric field occurs in an edge of semiconductor substrate 1. In field relaxation region 2a, a termination trench TT, p diffusion layer 5e, a field plate 3b, interlayer film 4b, and plug 4a are provided. Termination trench TT is structured so that electric field concentration onto a lower portion of element trench ET in element region 1a is relaxed without forming any deep p diffusion layer. Termination trench TT includes oxide film 5c and a termination trench electrode 5f. P diffusion layer 5e is structured so as to promote expansion of a depletion layer. P diffusion layer 5e is the first diffusion layer. P diffusion layer 5e is a field limiting ring. Field plate 3b is structured so that electric field concentration is relaxed on an interlayer film interface. Interlayer film 4b is structured so as to insulate upper and lower portions in different layers. Plug 4a is structured so as to allow interconnection between upper and lower portions in different layers.

In field relaxation region 2a, p diffusion layer 5e is provided in first surface S1. P diffusion layer 5e is a p-type impurity region. P diffusion layer 5e is in contact with n drift layer 6a. Field plate 3b is provided on plug 4a and interlayer film 4b.

Termination trench TT is provided in termination region 1b. Termination trench TT is structured so as to extend from first surface S1 toward second surface S2. Termination trench TT has a depth larger than the thickness of p diffusion layer 5e (the first diffusion layer). Termination trench TT passes through p diffusion layer 5e and is formed so as to be deeper than p diffusion layer 5e. Termination trench TT passes through p diffusion layer 5e and reaches n drift layer 6a. Trench TR is provided in termination region 1b. Oxide film 5c is provided on the inner surface of trench TR. Termination trench electrode 5f is provided on oxide film 5c. Termination trench electrode 5f is conductively connected to p diffusion layer 5e.

In channel stop region 2b, n channel stop layer 5g, field plate 3b, interlayer film 4b, and plug 4a are provided. N channel stop layer 5g is structured so as to inhibit expansion of a depletion layer. Field plate 3b is structured so that electric field concentration is relaxed on the interlayer film interface. Interlayer film 4b is structured so as to insulate upper and lower portions in different layers. Plug 4a is structured so as to allow interconnection between upper and lower portions in different layers.

In channel stop region 2b, n channel stop layer 5g is provided in first surface S1. N channel stop layer 5g is in contact with n drift layer 6a. N channel stop layer 5g is an n-type impurity region. Emitter electrode 3a is provided on plug 4a and interlayer film 4b.

The intervals among the plurality of element trenches ET in element region 1a are all equal normally, but may be different. An interval between element trenches ET in element region 1a is a first trench interval L1. First trench interval L1 is the interval between element trench ET included in the plurality of element trenches ET and situated closest to termination region 1b and element trench ET adjacent to element trench ET situated closest to termination region 1b. First trench interval L1 is, for example, 2 μm or more and 10 μm or less.

The plurality of element trenches ET include a first element trench ET1 and a second element trench ET2. First element trench ET1 is situated closest to termination region 1b. Second element trench ET2 is situated on the opposite side of termination region 1b in relation to first element trench ET1. Second element trench ET2 is situated so as to be adjacent to first element trench ET1. When the intervals among the plurality of element trenches ET are different, first trench interval L1 denotes the interval between first element trench ET1 and second element trench ET2.

The plurality of termination trenches TT include a first termination trench TT1 and a second termination trench TT2. First termination trench TT1 is situated closest to element region 1a. Second termination trench TT2 is situated on the opposite side of element region 1a in relation to first termination trench TT1. Second termination trench TT2 is situated so as to be adjacent to first termination trench TT1.

The interval between element trench ET included in the plurality of element trenches ET and situated closest to termination region 1b and termination trench TT included in the plurality of termination trenches TT and situated closest to element region 1a is a second trench interval L2. That is, the interval between element trench ET at the far end on the termination region 1b side and termination trench TT at the far end on the element region 1a side is second trench interval L2.

Second trench interval L2 is set so as not to be largely different from first trench interval L1. First trench interval L1 and second trench interval L2 are in a relation of L1≤L2≤1.5×L1. For example, first trench interval L1 is 4.0 μm and second trench interval L2 is 4.4 μm. When first trench interval L1 is larger than second trench interval L2 (L1>L2), a point of electric field concentration moves to element region 1a where the trench interval is wider than second trench interval L2. Thus, it is not preferable to make first trench interval L1 larger than second trench interval L2. Also, if the trench interval is changed abruptly such that second trench interval L2 exceeds the width that is 1.5 times as large as first trench interval L1, electric field concentration will be incurred. Thus, it is not preferable to make second trench interval L2 larger than the width that is 1.5 times as large as first trench interval L1. In addition, it is preferable to form termination trenches TT so that the intervals thereamong become wider with increase in distance from element region 1a. In the present embodiment, the intervals among termination trenches TT become wider with increase in distance from element region 1a.

Described next are functions and effects of semiconductor device 100 according to Embodiment 1.

In semiconductor device 100 according to Embodiment 1, first trench interval L1 and second trench interval L2 are in a relation of L1≤L2≤1.5×L1. If the trench interval is widened abruptly, electric field concentration will be caused. However, this relation between first trench interval L1 and second trench interval L2 enables it to relax electric field concentration. Accordingly, semiconductor device 100 high in withstand voltage can be attained.

### Embodiment 2

Unless otherwise described particularly, Embodiment 2 includes the same configuration, manufacture method, and functions and effects as those according to Embodiment 1.

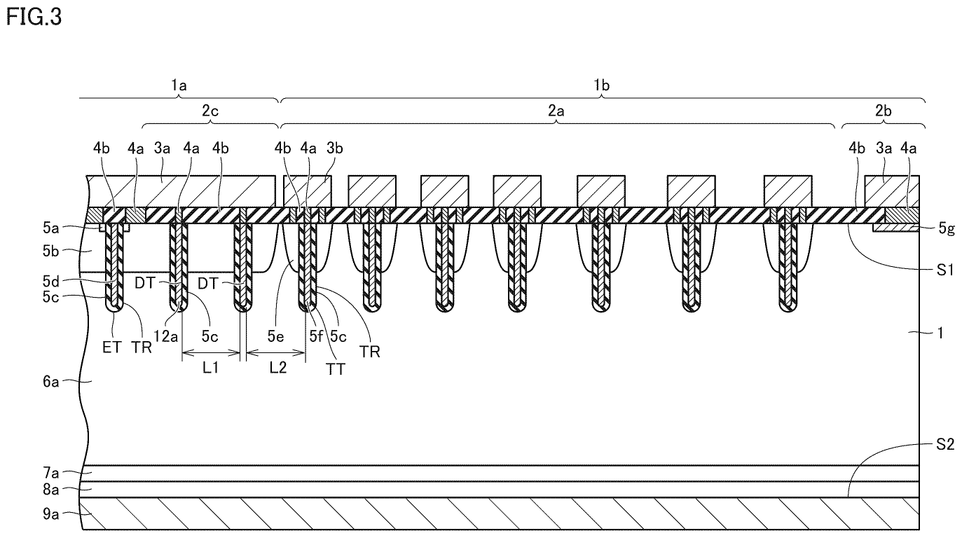

Referring to FIG. 3, in a semiconductor device 100 according to Embodiment 2, a boundary region 2c is provided on an end of an element region 1a. Element region 1a includes boundary region 2c. Boundary region 2c is adjacent to a termination region 1b. An element trench ET includes a dummy trench DT. In boundary region 2c, a p base layer 5b, dummy trench DT, an interlayer film 4b, and a plug 4a are provided. Dummy trench DT is a boundary trench. Dummy trench DT is a trench that does not include an n source layer 5a. Dummy trench DT passes through p base layer 5b and is formed so as to be deeper than p base layer 5b. Dummy trench DT includes an oxide film 5c and a boundary trench electrode 12a. Oxide film 5c is provided on the inner surface of a trench TR. Boundary trench electrode 12a is provided on oxide film 5c. Boundary trench electrode 12a is conductively connected to an emitter electrode 3a. Boundary trench electrode 12a may be conductively connected to a trench gate electrode 5d without being conductively connected to emitter electrode 3a. Interlayer film 4b is structured so as to insulate upper and lower portions in different layers. Plug 4a is structured so as to allow interconnection between upper and lower portions in different layers.

In semiconductor device 100 according to Embodiment 2, dummy trench DT is provided in boundary region 2c. Thus, current concentration to an end of element region 1a can be inhibited in a transition period from current conduction to current interruption. Accordingly, semiconductor device 100 high in breakdown strength and withstand voltage can be attained.

### Embodiment 3

Unless otherwise described particularly, Embodiment 3 includes the same configuration, manufacture method, and functions and effects as those according to Embodiment 1.

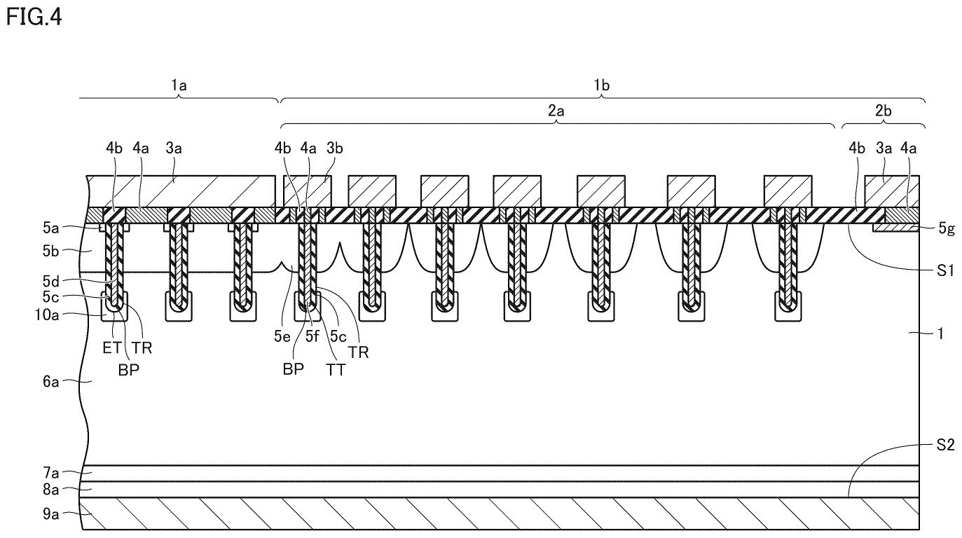

Referring to FIG. 4, in a semiconductor device 100 according to Embodiment 3, a p diffusion layer 10a is provided on a lower portion of each trench in an element region 1a and a termination region 1b. A semiconductor substrate 1 includes p diffusion layer 10a as a third diffusion layer. P diffusion layer 10a is of a second conductivity type. P diffusion layer 10a is a p-type impurity region. P diffusion layer 10a is in contact with an n drift layer 6a. P diffusion layer 10a is the third diffusion layer. P diffusion layer 10a (the third diffusion layer) is just needed to be provided on a bottom portion BP of at least one of an element trench ET and a termination trench TT. P diffusion layer 10a may be provided only on part of at least one of element trench ET and termination trench TT.

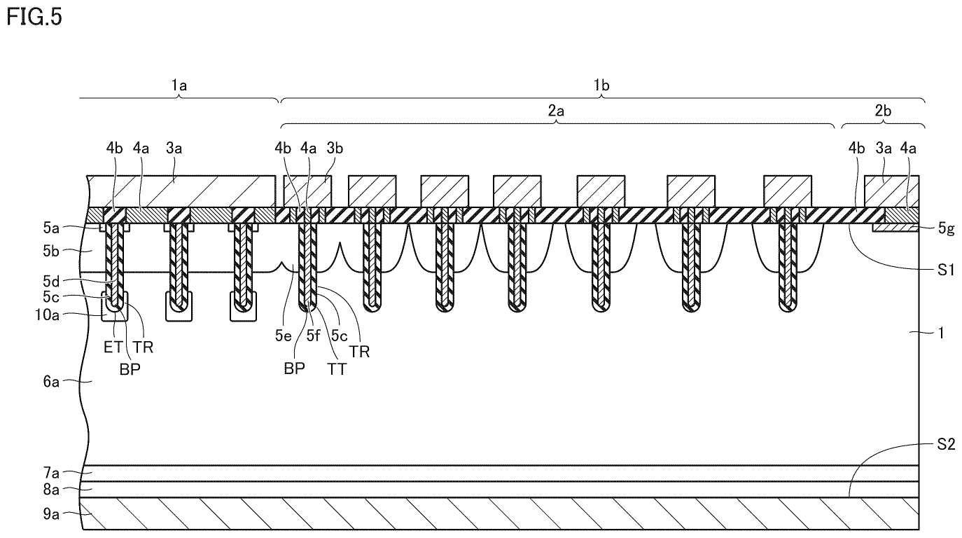

Referring to FIG. 5, in semiconductor device 100 according to Variation 1 of Embodiment 3, p diffusion layer 10a is provided only in element region 1a. That is, p diffusion layer 10a is provided in element region 1a and is not necessarily required to be provided in termination region 1b.

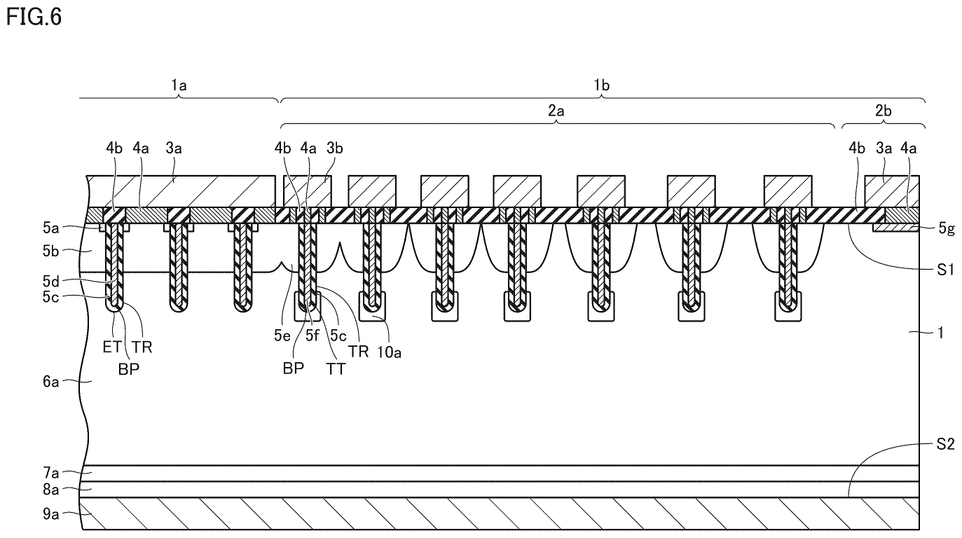

Referring to FIG. 6, in semiconductor device 100 according to Variation 2 of Embodiment 3, p diffusion layer 10a is provided only in termination region 1b. That is, p diffusion layer 10a is provided in termination region 1b and is not necessarily required to be provided in element region 1a.

In semiconductor device 100 according to Embodiment 3, p diffusion layer 10a (the third diffusion layer) is provided on bottom portion BP of at least one of element trench ET and termination trench TT. Thus, electric field concentration onto a lower portion of at least one of element trench ET and termination trench TT can be relaxed. Accordingly, a semiconductor device high in withstand voltage can be attained.

### Embodiment 4

Unless otherwise described particularly, Embodiment 4 includes the same configuration, manufacture method, and functions and effects as those according to Embodiment 1.

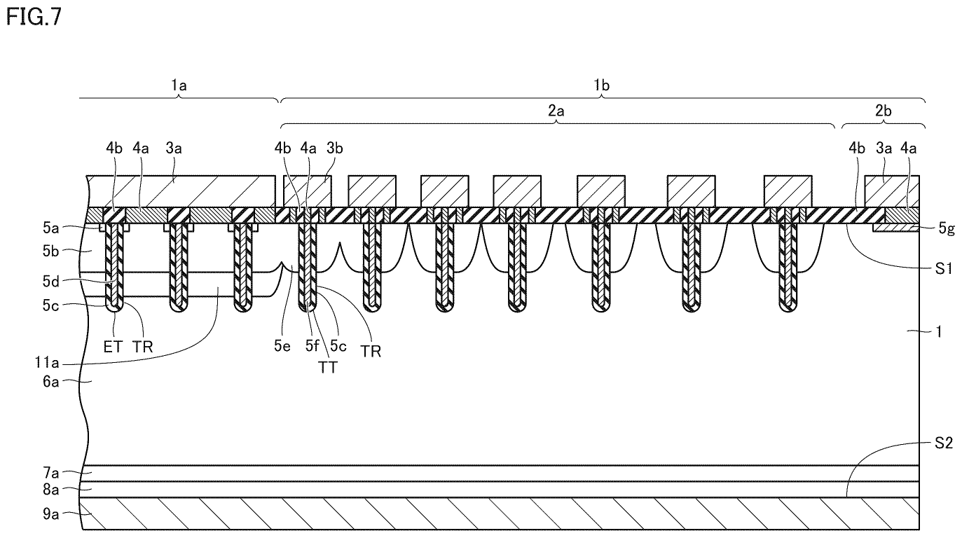

Referring to FIG. 7, in a semiconductor device 100 according to Embodiment 4, a carrier stored (CT) layer 11a is provided in an element region 1a. A semiconductor substrate 1 includes carrier stored layer 11a as a fourth diffusion layer. Carrier stored layer 11a is of a first conductivity type. Carrier stored layer 11a is an n-type impurity region. Carrier stored layer 11a is the fourth diffusion layer. In element region 1a, carrier stored layer 11a (the fourth diffusion layer) is situated between a p base layer 5b (a second diffusion layer) and a second surface S2 and is adjacent to p base layer 5b (the second diffusion layer).

In semiconductor device 100 according to Embodiment 4, in element region 1a, carrier stored layer 11a (the fourth diffusion layer) is situated between p base layer 5b (the second diffusion layer) and a second surface S2 and is adjacent to p base layer 5b (the second diffusion layer). Thus, element performance can be enhanced. Accordingly, semiconductor device 100 high in element performance and withstand voltage can be attained.

### Embodiment 5

Unless otherwise described particularly, Embodiment 5 includes the same configuration, manufacture method, and functions and effects as those according to Embodiments 3 and 4.

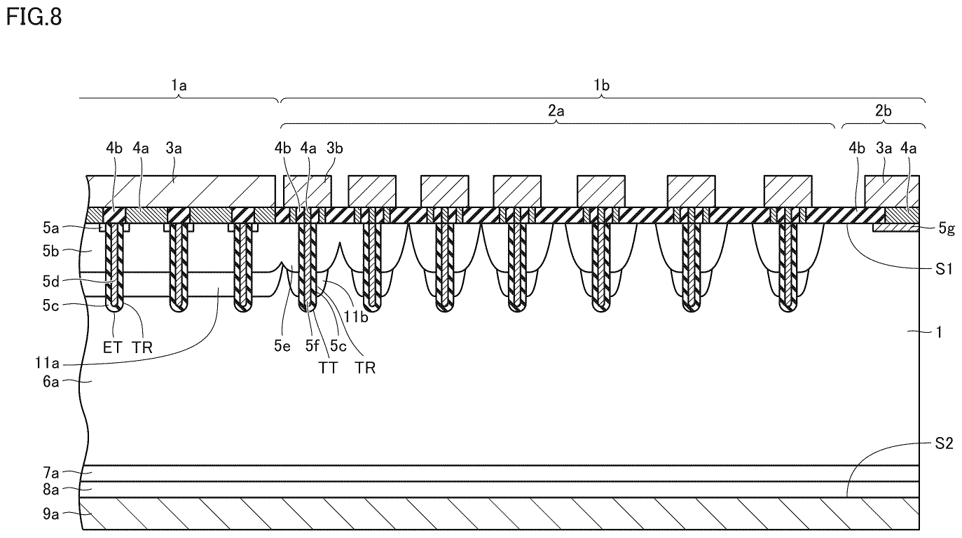

Referring to FIG. 8, in a semiconductor device 100 according to Embodiment 5, a carrier stored layer 11a is provided in an element region 1a and an n diffusion layer 11b is provided in a termination region 1b. A semiconductor substrate 1 includes n diffusion layer 11b as a fifth diffusion layer. N diffusion layer 11b is of a first conductivity type. N diffusion layer 11b is an n-type impurity region. N diffusion layer 11b is the fifth diffusion layer. In termination region 1b, n diffusion layer 11b (the fifth diffusion layer) is situated between a p diffusion layer 5e (a first diffusion layer) and a second surface S2 and is adjacent to p diffusion layer 5e (the first diffusion layer).

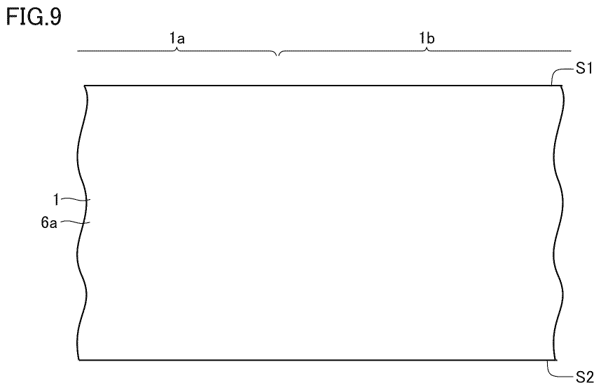

Referring next to FIGS. 9 to 15, a method for manufacturing semiconductor device 100 according to Embodiment 5 is described.

As illustrated in FIG. 9, semiconductor substrate 1 is prepared, which includes a first surface S1 and second surface S2 opposite to each other. Semiconductor substrate 1 includes an n drift layer 6a as a drift layer.

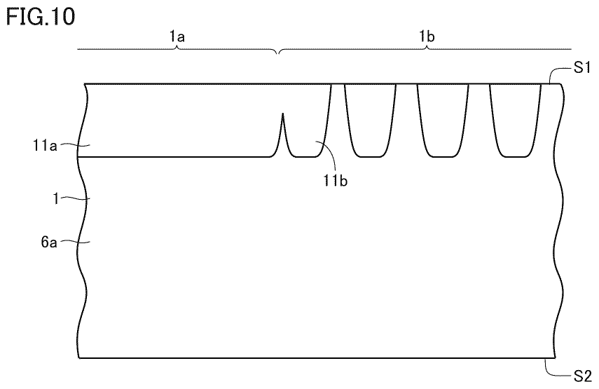

As illustrated in FIG. 10, in an ion implantation step, carrier stored layer 11a and n diffusion layer 11b are concurrently formed in semiconductor substrate 1 using a mask. Carrier stored layer (a fourth diffusion layer) 11a in element region 1a and n diffusion layer 11b (the fifth diffusion layer) in termination region 1b are concurrently formed. In element region 1a, carrier stored layer 11a is situated between a p base layer 5b (a second diffusion layer) and second surface S2. Carrier stored layer 11a is adjacent to p base layer 5b (the second diffusion layer). In termination region 1b, n diffusion layer 11b is situated between p diffusion layer 5e (the first diffusion layer) and second surface S2. N diffusion layer 11b is adjacent to p diffusion layer 5e (the first diffusion layer).

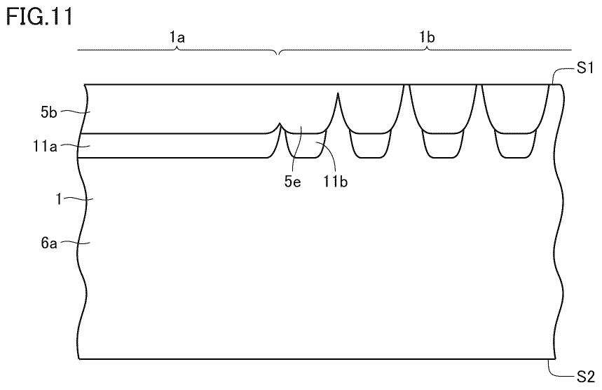

As illustrated in FIG. 11, in the ion implantation step, p base layer 5b and p diffusion layer 5e are concurrently formed using the same mask as the mask used when carrier stored layer 11a and n diffusion layer 11b are formed. That is, p diffusion layer 5e (the first diffusion layer) in termination region 1b and p base layer 5b (the second diffusion layer) in element region 1a are concurrently formed in semiconductor substrate 1. P diffusion layer 5e (the first diffusion layer) is situated in first surface S1. P diffusion layer 5e (the first diffusion layer) is of a second conductivity type different from the first conductivity type of n drift layer 6a. P base layer 5b (the second diffusion layer) is situated in first surface S1. P base layer 5b (the second diffusion layer) is of the second conductivity type. Without forming n diffusion layer 11b, only carrier stored layer 11a may be formed using a mask different from the mask used when carrier stored layer 11a and n diffusion layer 11b are formed.

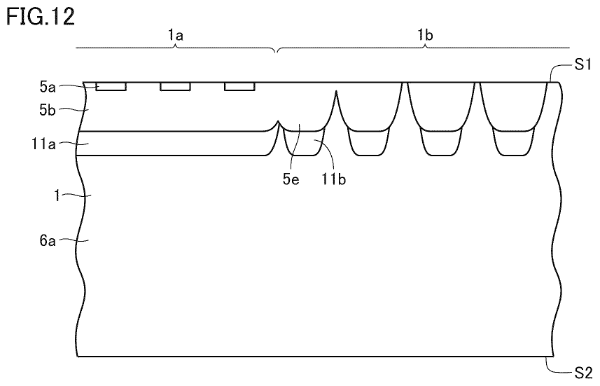

As illustrated in FIG. 12, an n source layer 5a is formed in the ion implantation step.

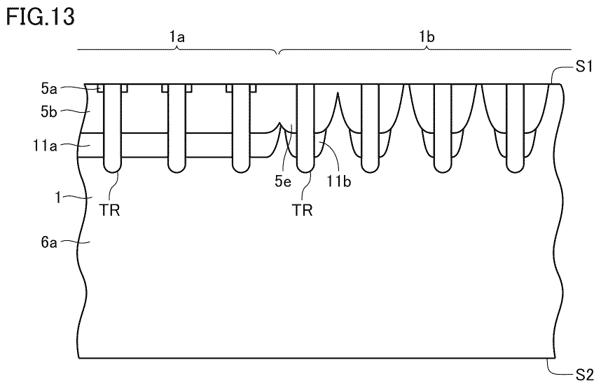

As illustrated in FIG. 13, trenches TR are concurrently shaped in element region 1a and termination region 1b in an anisotropic etching step. Trenches TR in element region 1a and termination region 1b are concurrently formed.

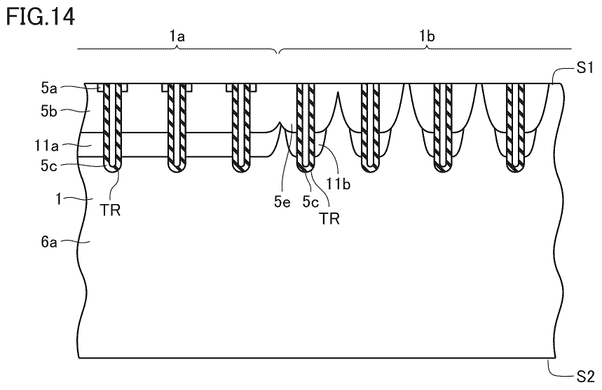

As illustrated in FIG. 14, oxide films 5c, which are made as silicon oxide films for example, are concurrently formed on the inner surfaces of trenches TR in element region 1a and termination region 1b in an oxidation step.

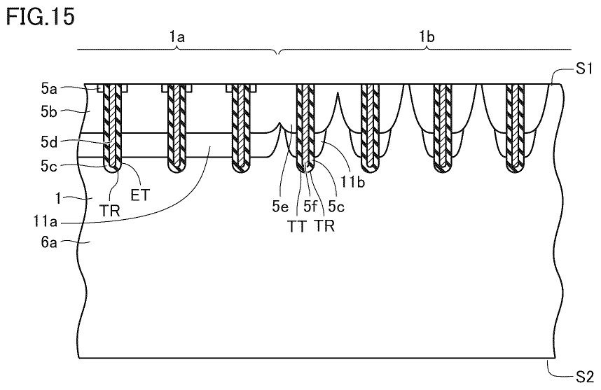

As illustrated in FIG. 15, trench gate electrodes 5d and termination trench electrodes 5f, which are made from polysilicon having conductivity for example, are concurrently formed inside oxide films 5c in trenches TR in element region 1a and termination region 1b. In this manner, element trenches ET that are structured so as to extend from first surface S1 toward second surface S2 in element region 1a and termination trenches TT that are structured so as to extend from first surface S1 toward second surface S2 in termination region 1b are concurrently formed. The respective structures of element trench ET and termination trench TT are similar to those in semiconductor device 100 according to Embodiment 1.

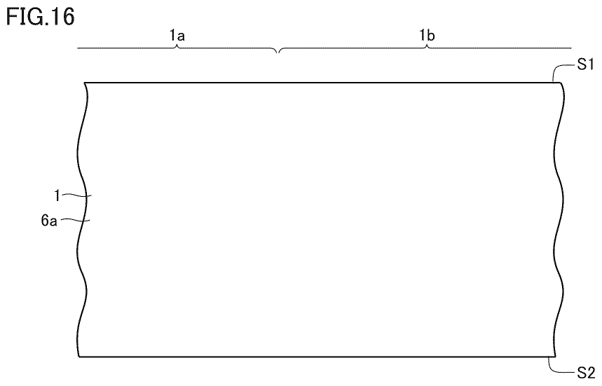

Furthermore, referring to FIGS. 16 to 23, a variation of the method for manufacturing semiconductor device 100 according to Embodiment 5 is described.

The variation of the method for manufacturing semiconductor device 100 according to Embodiment 5 is mainly different from the method for manufacturing semiconductor device 100 according to Embodiment 5 in the following respects. In the variation of the method for manufacturing semiconductor device 100 according to Embodiment 5, p base layer 5b and p diffusion layer 5e are formed apart from each other. P diffusion layers 5e are all formed apart from one another. A p diffusion layer 10a is formed.

As illustrated in FIG. 16, semiconductor substrate 1 is prepared.

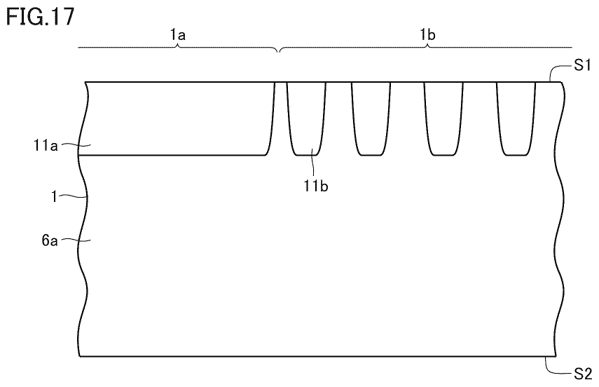

As illustrated in FIG. 17, in the ion implantation step, carrier stored layer 11a and n diffusion layer 11b are concurrently formed in semiconductor substrate 1 using a mask. That is, carrier stored layer 11a (the fourth diffusion layer) in element region 1a and n diffusion layer 11b (the fifth diffusion layer) in termination region 1b are concurrently formed.

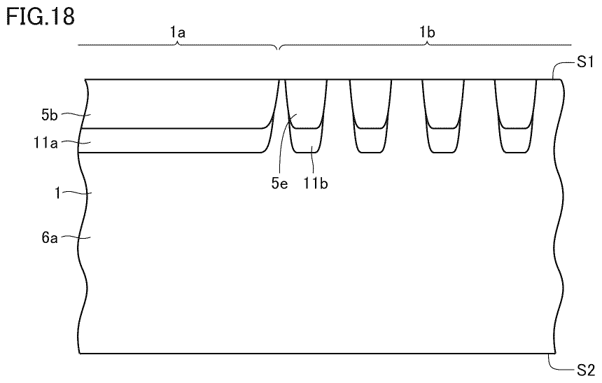

As illustrated in FIG. 18, p diffusion layer 5e (the first diffusion layer) in termination region 1b and p base layer 5b (the second diffusion layer) in element region 1a are concurrently formed in semiconductor substrate 1. P base layer 5b and p diffusion layer 5e are formed apart from each other. P diffusion layers 5e are all formed apart from one another.

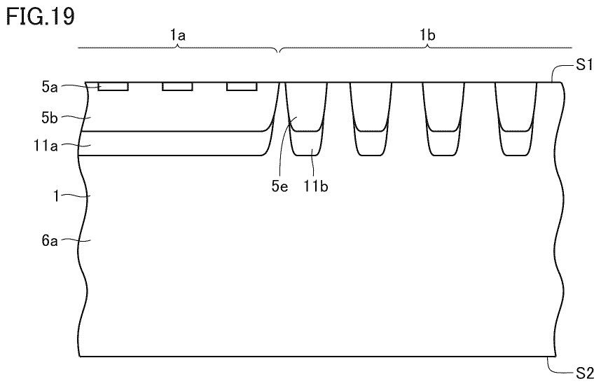

As illustrated in FIG. 19, n source layer 5a is formed in the ion implantation step.

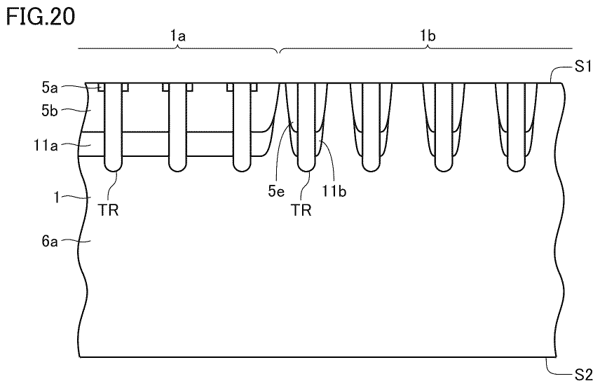

As illustrated in FIG. 20, trenches TR are concurrently shaped in element region 1a and termination region 1b in the anisotropic etching step. Trenches TR in element region 1a and termination region 1b are concurrently formed.

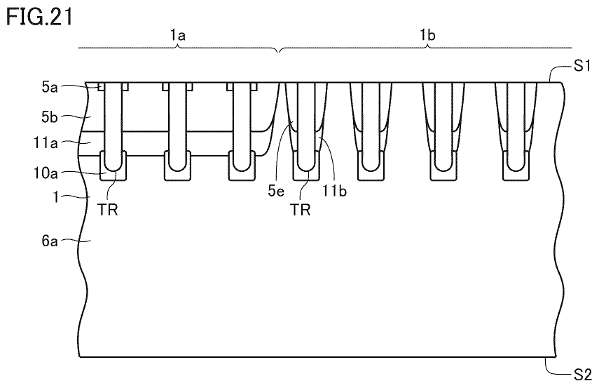

As illustrated in FIG. 21, p diffusion layers 10a are concurrently formed in element region 1a and termination region 1b in the ion implantation step.

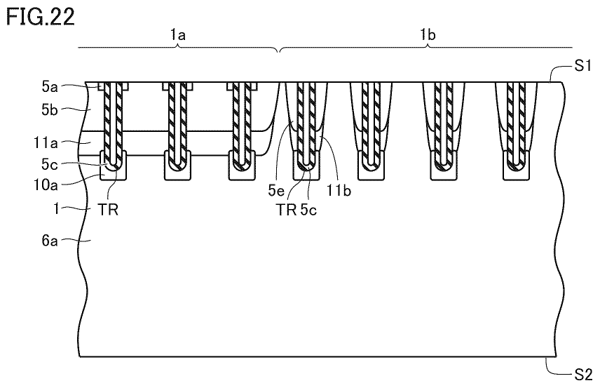

As illustrated in FIG. 22, oxide films 5c are concurrently formed on the inner surfaces of trenches TR in element region 1a and termination region 1b in the oxidation step.

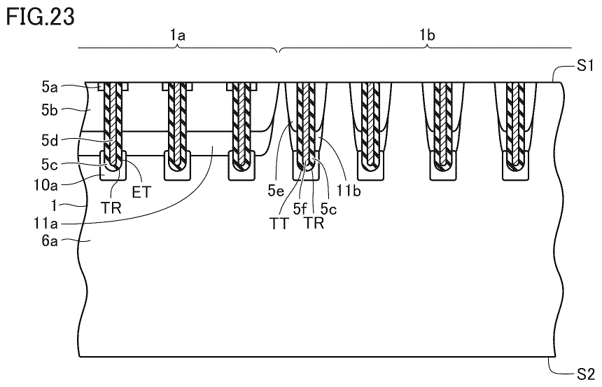

As illustrated in FIG. 23, trench gate electrodes 5d and termination trench electrodes 5f are concurrently formed inside oxide films 5c in trenches TR in element region 1a and termination region 1b.

Described next are functions and effects according to Embodiment 5.

In semiconductor device 100 according to Embodiment 5, in termination region 1b, n diffusion layer 11b (the fifth diffusion layer) is situated between p diffusion layer 5e (the first diffusion layer) and second surface S2 and is adjacent to p diffusion layer 5e (the first diffusion layer). Thus, manufacturing processes can be simplified while element performance can be enhanced. Accordingly, semiconductor device 100 low in manufacturing cost and high in withstand voltage can be attained.

By the method for manufacturing semiconductor device 100 according to Embodiment 5, p diffusion layer 5e (the first diffusion layer) and p base layer 5b (the second diffusion layer) are concurrently formed. Thus, manufacturing processes can be simplified. Accordingly, semiconductor device 100 low in manufacturing cost and high in withstand voltage can be attained.

By the method for manufacturing semiconductor device 100 according to Embodiment 5, trenches TR are concurrently formed in element region 1a and termination region 1b. Thus, manufacturing processes can be simplified. Accordingly, semiconductor device 100 high in element performance and withstand voltage and low in manufacturing cost can be attained.

By the method for manufacturing semiconductor device 100 according to Embodiment 5, carrier stored layer 11a (the fourth diffusion layer) and n diffusion layer 11b (the fifth diffusion layer) are concurrently formed. Thus, manufacturing processes can be simplified. Accordingly, semiconductor device 100 low in manufacturing cost and high in withstand voltage can be attained.

The embodiments described above can be combined as necessary.

It should be understood that the herein-disclosed embodiments are presented by way of illustration and example in every respect and are not to be taken by way of limitation. The scope of the present disclosure is not defined by the description above but is defined by the claims, and is intended to include all changes within the purport and scope equivalent to the claims.

### REFERENCE SIGNS LIST

1 semiconductor substrate, 1a element region, 1b termination region, 2a field relaxation region, 2b channel stop region, 2c boundary region, 3a emitter electrode, 3b field plate, 4a plug, 4b interlayer film, 5a n source layer, 5b p base layer, 5c oxide film, 5d trench gate electrode, 5e p diffusion layer, 10a p diffusion layer, 11b n diffusion layer, 5f termination trench electrode, 5g channel stop layer, 6a n drift layer, 7a n buffer layer, 8a p collector layer, 9a collector electrode, 11a carrier stored layer, 12a boundary trench electrode, 100 semiconductor device, BP bottom portion, DT dummy trench, ET element trench, L1 first trench interval, L2 second trench interval, S1 first surface, S2 second surface, TT termination trench.

1. A semiconductor device comprising:
a semiconductor substrate that includes a first surface and a second surface opposite to each other and includes an element region and a termination region provided so as to surround the element region;
a plurality of element trenches provided in the element region and structured so as to extend from the first surface toward the second surface; and
a plurality of termination trenches provided in the termination region and structured so as to extend from the first surface toward the second surface, wherein
the semiconductor substrate includes a drift layer of a first conductivity type, a first diffusion layer, and a second diffusion layer, the first diffusion layer being situated in the first surface in the termination region and being of a second conductivity type different from the first conductivity type of the drift layer, the second diffusion layer being situated in the first surface in the element region and being of the second conductivity type,
the element trench has a depth larger than a thickness of the second diffusion layer,
the termination trench has a depth larger than a thickness of the first diffusion layer, and
a first trench interval L1 and a second trench interval L2 are in a relation of L1≤L2≤1.5×L1, where
the first trench interval L1 is an interval between the element trench included in the plurality of element trenches and situated closest to the termination region and the element trench adjacent to the element trench situated closest to the termination region, and
the second trench interval L2 is an interval between the element trench included in the plurality of element trenches and situated closest to the termination region and the termination trench included in the plurality of termination trenches and situated closest to the element region.

2. The semiconductor device according to claim 1, wherein
the element region includes a boundary region adjacent to the termination region,
the element trench includes a dummy trench, and
the dummy trench is provided in the boundary region.

3. The semiconductor device according to claim 1, wherein
the semiconductor substrate includes a third diffusion layer of the second conductivity type, and
the third diffusion layer is provided on a bottom portion of at least one of the element trench and the termination trench.

4. The semiconductor device according to claim 1, wherein
the semiconductor substrate includes a fourth diffusion layer of the first conductivity type, and
in the element region, the fourth diffusion layer is situated between the second diffusion layer and the second surface and is adjacent to the second diffusion layer.

5. The semiconductor device according to claim 4, wherein
the semiconductor substrate includes a fifth diffusion layer of the first conductivity type, and
in the termination region, the fifth diffusion layer is situated between the first diffusion layer and the second surface and is adjacent to the first diffusion layer.

6. A method for manufacturing a semiconductor device, the method comprising:
preparing a semiconductor substrate that includes a first surface and a second surface opposite to each other and includes a drift layer of a first conductivity type;
concurrently forming a first diffusion layer and a second diffusion layer in the semiconductor substrate, the first diffusion layer being situated in the first surface in a termination region and being of a second conductivity type different from the first conductivity type of the drift layer, the second diffusion layer being situated in the first surface in an element region and being of the second conductivity type; and
forming element trenches and termination trenches, the element trench being structured so as to extend from the first surface toward the second surface in the element region, the termination trench being structured so as to extend from the first surface toward the second surface in the termination region, wherein
the element trench has a depth larger than a thickness of the second diffusion layer,
the termination trench has a depth larger than a thickness of the first diffusion layer, and
a first trench interval L1 and a second trench interval L2 are in a relation of L1≤L2≤1.5×L1, where
the first trench interval L1 is an interval between the element trench included in the element trenches and situated closest to the termination region and the element trench adjacent to the element trench situated closest to the termination region, and
the second trench interval L2 is an interval between the element trench included in the element trenches and situated closest to the termination region and the termination trench included in the termination trenches and situated closest to the element region.

7. The method for manufacturing a semiconductor device according to claim 6, wherein in the forming of the element trenches and the termination trenches, trenches are concurrently formed in the element region and the termination region.

8. The method for manufacturing a semiconductor device according to claim 6, the method further comprising concurrently forming a fourth diffusion layer of the first conductivity type and a fifth diffusion layer of the first conductivity type, the fourth diffusion layer being situated between the second diffusion layer and the second surface and being adjacent to the second diffusion layer in the element region, the fifth diffusion layer being situated between the first diffusion layer and the second surface and being adjacent to the first diffusion layer in the termination region.
